(19) United States
(12) Patent Application Publication
(10) Pub. No.: US 2005/0124176 A1
(43) Pub. Date: Jun. 9, 2005

(54) Semiconductor device and method for fabricating the same and semiconductor device application system

(76) Inventors: Takashi Sugino, Osaka (JP); Masaki Kusuhara, Tokyo (JP); Masaru Umeda, Tokyo (JP)

Correspondence Address: RANDALL J. KNUTH P.C., 4921 DESOTO DRIVE, FORT WAYNE, IN, 46815, US

(21) Appl. No.: 10/484,371

(22) PCT Filed: Jul. 17, 2002
(86) PCT No.: PCT/JP02/07279

(30) Foreign Application Priority Data
Jul. 17, 2001 (JP) 2001-217090

(51) Int. Cl. H01L 23/58; H01L 21/26; H01L 21/324; H01L 21/42; H01L 21/477

(52) U.S. Cl. 438/795; 257/632

(57) ABSTRACT

A semiconductor surface treatment and a film deposition method capable of realizing surface protection and surface inactivation using a boron nitride film is provided. A high-performance semiconductor device can be manufactured by using the same surface protection technology and surface inactivation technology. Additionally, a electronic device for a communication system or a high-performance information processing device may incorporate such a semiconductor device.

### BACKGROUND OF THE INVENTION

1. Field of the Invention

The present invention concerns performance improvement of a semiconductor device through the protection and the inactivation of a semiconductor surface.

2. Description of the Related Art

A field effect transistor (FET) and a Hetero Bipolar Transistor (HBT) are developed for use in a high frequency electric device. A surface level generation occurs due to a dangling bond and/or oxidation of the semiconductor surface. Such generation is provoked on the semiconductor surface exposed between the FET gate and drain and between the FET source and gate or on the edges of an HBT base area. The deterioration of transistor performance thus results. Increased leak of current between the gate and the drain may be observed for the FET, while few carriers decrease in the base as the surface recombination occurs for the HBT.

Electronic devices composed of group-III nitrogen compounds are expected to form the next generation of high frequency power devices. However, it is difficult to easily apply a manufacturing process technology of the electronic device when using a chemical compound semiconductor such as conventional GaAs—AlGaAs type material. It is impossible to sufficiently bring out the characteristics of new group-III nitrogen compound materials using only silicon oxide film or silicon nitride film, i.e., the types of films that have typically been used for the semiconductor surface protection or the inactivation film. Thus, it is necessary to introduce a novel semiconductor surface protection technology and a surface inactivation technology.

### SUMMARY OF THE INVENTION

The development of the surface protection technology and the surface inactivation technology for group-Ill nitride semiconductors and the accompanying performance improvement of the high frequency electronic devices are in demand. The present invention has been devised in view of the aforementioned situation, and an objective of the present invention is to provide a semiconductor surface treatment and a film deposition method capable of realizing surface protection and surface inactivation, using boron nitride film, a high performance semiconductor device manufactured by using the same surface protection technology and surface inactivation technology and an electronic device for communication systems including a semiconductor device.

The semiconductor device of the present invention provides a film comprising at least boron and nitrogen atoms.

Moreover, the semiconductor device of the present invention can further include one or more of aluminum, gallium, indium, phosphorus, carbon and silicon in the film.

Moreover, the semiconductor device of the present invention advantageously has a composite film structure of the film and a silicon nitride film.

Moreover, the semiconductor device of the present invention uses the film as any one of a semiconductor surface protection film, a surface inactivation film, and a wiring interlayer insulation film.

Moreover, the semiconductor device of the present invention can employ group-III nitride semiconductor heterojunctions.

Moreover, the semiconductor device of the present invention can include group-V nitride semiconductor heterojunctions.

Moreover, a manufacturing method of the semiconductor device of the present invention may involve arranging a substrate for deposition in a plasma atmosphere including nitrogen, supplying the substrate with boron atoms, and forming a boron nitride film.

Moreover, the manufacturing method of the semiconductor device of the present invention can advantageously include forming a boron nitride film on the substrate by laser abrasion or spattering of boron nitride.

Moreover, the manufacturing method of the semiconductor device of the present invention can advantageously employ a step of supplying as an additional atom any one among aluminum, gallium, indium, phosphorus, carbon and silicon thereto during the manufacturing of the film.

Moreover, the manufacturing method of the semiconductor device of the present invention may include exposing the surface of the substrate in a plasma including at least one element of hydrogen, nitrogen, argon and phosphorus before the manufacturing of the film.

Moreover, a communication system device of the present invention can advantageously employ the semiconductor device manufactured by the present invention.

Moreover, an information-processing device of the present invention can usefully employ the semiconductor device manufactured by the present invention.

### BRIEF DESCRIPTION OF DRAWINGS

The above-mentioned and other features and advantages of this invention, and the manner of attaining them, will become more apparent and the invention will be better understood by reference to the following description of multiple embodiments of the invention taken in conjunction with the accompanying drawings, wherein:

FIG. 1 is a cross-section view showing a semiconductor device according to an embodiment 1 of the present invention; and

FIG. 2 is a cross-section view showing a semiconductor device according to an embodiment 2 of the present invention.

Corresponding reference characters indicate corresponding parts throughout the several views. The exemplifications set out herein illustrate at least one preferred embodiment of the invention, in one form, and such exemplifications are not to be construed as limiting the scope of the invention in any manner.

Description of Symbols

1 substrate
2 AlN buffer layer
3 non-doped GaN layer
4-1 non-doped AlGaN spacer layer
4-2 n-type AlGaN layer
4-3 non-doped AlGaN cap layer
5 Source
6 Drain
7 Gate
8-1 Boron nitride film
8-2 Silicon nitride film
21 Substrate
22 n-type AlN buffer layer
23 n-type GaN collector layer
24 p-type GaN base layer
25 n-type AlGaN emitter layer
26 n-type GaN contact layer
27-1 Boron nitride layer
27-2 Silicon nitride layer
28 Emitter electrode
29 Base electrode
30 Collector electrode

### DETAILED DESCRIPTION OF THE INVENTION

Now, the embodiments of the present invention shall be described in detail referring to attached drawings.

### EMBODIMENT 1

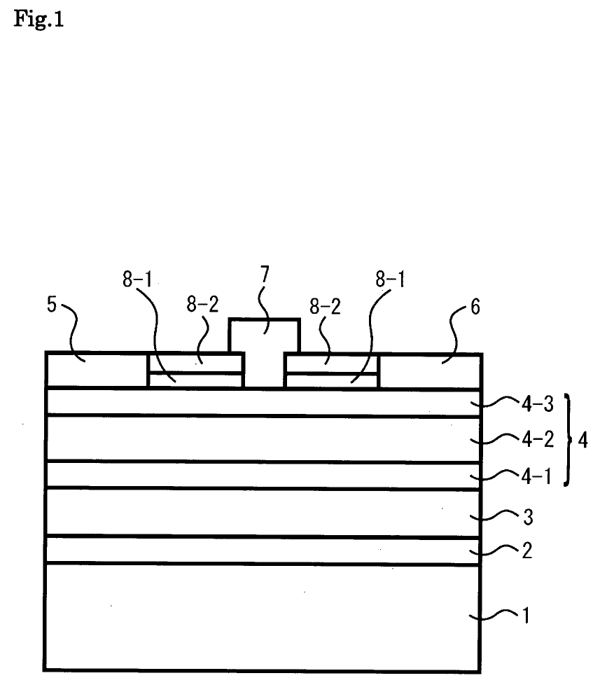

FIG. 1 is a schematic side view showing a hetero FET as a semiconductor device, according to a first embodiment of the present invention. An AlN buffer layer 2 is formed on a sapphire substrate 1 by a metal organic chemical vapor deposition method (MOCVD). Furthermore, a non-doped GaN layer 3 is deposited at a thickness of 2 μm, a non-doped AlGaN spacer layer 4-1 (2 nm thick), a Si added n-type AlGaN layer 4-2 (15 nm thick), and a non-doped AlGaN cap layer 4-3 (3 nm thick).

After the element isolation, the sample temperature is raised to 300° C. in a plasma CVD device for processing the surface with a hydrogen plasma before depositing a boron nitride layer 8-1. A 50 nm thick born nitride layer 8-1 is then formed using a nitrogen plasma and boron trichloride. A silicon nitride film 8-2 is deposited to a thickness of 300 nm thereon using a spattering method. The boron nitride layer 8-1 and silicon nitride film 8-2 of a source 5 and a drain 6 are etched by photolithography. Thereafter, electronic beam vapor deposition of Ti/Al is executed and an ohmic electrode is formed. Next, in order to form a gate 7 electrode between the source 5 and drain 6 electrodes, the silicon nitride film 8-2 and boron nitride layer 8-1 are etched, and thereafter, the gate 7 electrode is created by forming a Schottky junction with Ni/Au.

By manufacturing the hetero FET in this way, the gate and drain leak current is able to be reduced to one third or less of that of those using only a silicon oxide film or a silicon nitride film as the surface protection between the source and gate and the gate and drain.

Though the sapphire is used for the substrate in this embodiment, SiC may also be used. In addition, without limiting to the FET having the GaN/AlGaN layer structure used in this embodiment, it is used similarly for FET's having other layer structures.

### EMBODIMENT 2

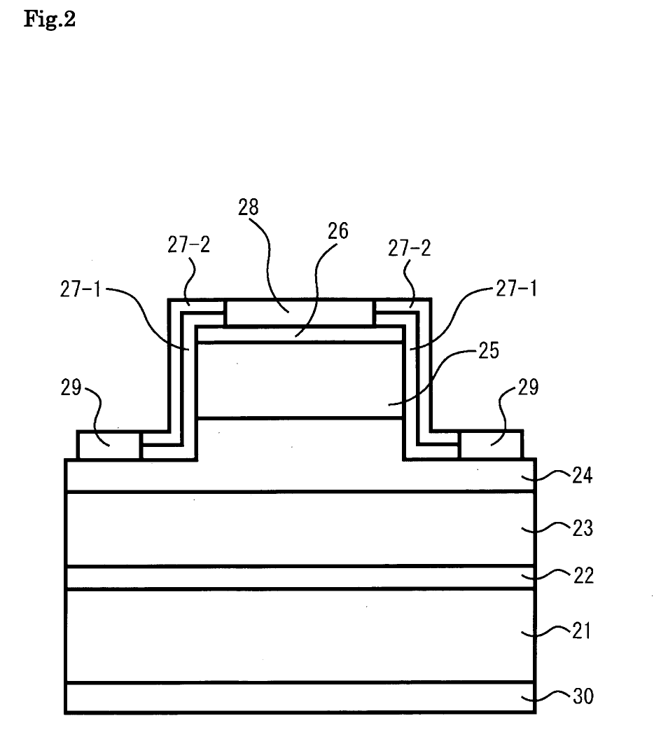

FIG. 2 is a schematic side view showing an HBT as a semiconductor device according to a second embodiment of the present invention. An Si-added n-type AlN buffer layer 22 is formed on an n-type SiC substrate 21 by a metal organic chemical vapor deposition method (MOCVD). Furthermore, an n-type GaN collector layer 23 is deposited (2 μm thick), a Mg-added p-type GaN base layer 24 (0.3 μm thick), an Si-added n-type AlGaN emitter layer 25 (1 μm thick) and an n-type GaN contact layer 26 (50 nm thick). After the element isolation, the contact layer 26 and the emitter layer 25 are removed leaving the emitter part, and the base layer 24 is exposed. The sample temperature is raised to 300° C. in the plasma CVD device for processing the surface with hydrogen plasma, before a boron nitride layer 27-1 is deposited to a thickness of 50 nm using a nitrogen plasma and boron trichloride.

A silicon nitride film 27-2 is deposited (300 nm) thereon using the spattering method. The silicon nitride film 27-2 and boron nitride layer 27-1 of the emitter electrode 28 part are etched by photolithography, electronic beam vapor deposition of Ti/Al is executed, and an emitter electrode is formed. Similarly, the silicon nitride film 27-2 and boron nitride layer 27-1 of a base electrode 29 are etched by the photolithography, electronic beam vapor deposition of Ni/Al, is executed and a base electrode is formed. Finally, a collector electrode 30 is formed on the back of the substrate 21 to complete the device.

By manufacturing the HBT in this way, the emitter earth current amplification rate has increased by 50% or more over that of those using only a silicon oxide film or a silicon nitride film for surface protection of the base layer 24.

Though the n-type SiC is used as the substrate in the present embodiment, a sapphire or an SiC high-resistance substrate may also be used. In using the high-resistance substrate, the collector electrode is also manufactured on the surface side using a similar manufacturing process. In addition, without limiting to the HBT having the GaN/AlGaN layer structure used in this embodiment, it is used similarly for HBT's having other layer structures.

If used for group III to group V compound semiconductor devices (for instance, GaAs FET, GaAs/AlGaAs HEMT, AllnAs/InGaAs HEMT and so on), a stray capacitance could be reduced for a low dielectric constant film, and the frequency characteristics of the element could be improved.

Industrial Applicability

The present invention provides a method for reducing a surface defect density by manufacturing a boron nitride film on the semiconductor surface. This method can be applied to the manufacturing of semiconductor devices such as an FET and an HBT. Especially, it is effective for improving a high-frequency electric element performance via the use of a nitride semiconductor for the FET and the HBT.

Moreover, the semiconductor devices manufactured by using the technology according to the present invention can be used for a key device for a high-performance information processing device, a communication system device and so on.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1. A semiconductor device, comprising a first film including at least boron and nitrogen atoms.

2. The semiconductor device according to claim 1, wherein said film includes at least one of Al, Ga, In, P, C, and Si.

3. The semiconductor device according to claim 1, comprising a composed film structure of said first film and a silicon nitride film.

4. The semiconductor device according to claim 1, comprising a compound film structure of said first film and a silicon oxide film.

5. The semiconductor device according to claim 1, wherein said first film is configured for use as at least one of a surface protection film, a surface inactivated film, and a wiring interlayer isolation film of semiconductor.

6. The semiconductor device according to claim 1, further comprising a group-III nitride compound semiconductor heterojunction.

7. The semiconductor device according to claim 1, further comprising a group-Ill to group-V nitride compound semiconductor heterojunction.

8. The semiconductor device according to claim 1, wherein the semiconductor device is an FET.

9. The semiconductor device according to claim 1, wherein the semiconductor device is an HBT.

10. A manufacturing method of a semiconductor device, comprising the steps of:
arranging a substrate in a plasma atmosphere, the plasma atmosphere including nitrogen;
supplying boron atoms onto the substrate, and
forming a boron nitride film on the substrate.

11. A manufacturing method of a semiconductor device, comprising the steps of:
providing a substrate; and
forming a boron nitride film onto the substrate by laser abrasion or spatter of boron nitride thereupon.

12. The manufacturing method of the semiconductor device according to claim 10, further comprising the step of supplying at least one of Al, Ga, In, P, C and Si as an additional atom when forming the film.

13. The manufacturing method of a semiconductor device according to claim 10 or 11, further comprising the step of making the exposing a surface of the substrate to be upon which the film is formed to a plasma including at least one element of H, N, Ar and P before forming the film.

14. The semiconductor device according to claim 10, wherein the semiconductor device is an FET.

15. The semiconductor device according to claim 10, wherein the semiconductor device is an HBT.

16. A communication system device having the semiconductor device according claim 1.

17. An information processing system device having the semiconductor device according to claim 1.

18. The manufacturing method of the semiconductor device according to claim 11, further comprising the step of supplying at least one of Al, Ga, In, P, C and Si as an additional atom when forming the film.

19. The manufacturing method of a semiconductor device according to claim 11, further comprising the step of exposing a surface of the substrate to be upon which the film is formed to a plasma including at least one element of H, N, Ar and P before forming the film.

20. The semiconductor device according to claim 11, wherein the semiconductor device is an FET.

21. The semiconductor device according to claim 11, wherein the semiconductor device is an HBT.

22. A semiconductor device, comprising:
a substrate, said substrate being composed of one of sapphire, M-type SiC, and an SiC high-resistance material; and
a first film formed on said substrate, said first film include at least boron and nitrogen, said first film being configured for use as at least one of a surface protection film and a surface inactivated film.
